(19) United States
(12) Patent Application Publication
(10) Pub. No.: US 2005/0214694 A1
(43) Pub. Date: Sep. 29, 2005

(54) Pattern formation method

(75) Inventors: Jin Hong, Hwaseong-si (KR); Hyun-Woo Kim, Hwaseong-si (KR); Myoung-Ho Jung, Yongin-si (KR); Gyung-Jin Min, Seoul (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/010,602

(22) Filed: Dec. 13, 2004

(30) Foreign Application Priority Data
Dec. 13, 2003 (KR) 2003-90941

(51) Int. Cl. G03F 7/00

(52) U.S. Cl. 430/323; 430/322

(57) ABSTRACT

A pattern formation method comprises forming a material layer on a substrate, forming an amorphous carbon layer on the material layer, forming an anti-reflective layer on the amorphous carbon layer, forming a silicon photoresist layer on the anti-reflective layer, forming a silicon photoresist layer pattern by patterning the silicon photoresist layer, etching the anti-reflective layer and the amorphous carbon layer using the silicon photoresist layer pattern as an etch mask to form an amorphous carbon layer pattern, and etching the material layer using the amorphous carbon layer pattern as an etch mask to form a pattern in the material layer.

### CROSS-REFERENCE TO RELATED APPLICATION

This application claims priority to Korean Patent Application No. 2003-90941, filed on Dec. 13, 2003, in the Korean Intellectual Property Office, the disclosure of which is incorporated herein in its entirety by reference.

### TECHNICAL FIELD

The present invention relates to a method of manufacturing a semiconductor device, and more particularly, to a pattern formation method of a semiconductor device using an amorphous carbon layer and a silicon photoresist layer.

### BACKGROUND

As a semiconductor device becomes more highly integrated, the dimensions of the photoresist pattern are reduced, and equipment capable of forming minute photoresist patterns is needed. In general, a pattern can be formed by photolithography. For example, a hard mask layer used as an etch mask, an anti-reflective layer, and a photoresist layer are deposited on a material layer where a pattern is to be formed. Then processes such as exposure, development, etching, ashing and stripping are performed to form a certain pattern in the material layer. Conventionally, a multilayer amorphous carbon layer/silicon oxynitride (SiON) layer/anti-reflective layer/photoresist layer structure is used for fine pattern formation of sub-micron integrated semiconductor devices such as about 82 nm semiconductor devices.

The conventional multilayer structure is used for patterning a material layer formed between an amorphous carbon layer and a substrate. The material layer may be, for example, an oxide layer or a nitride layer. A photoresist layer pattern, which may be formed by exposure and development processes, is transferred into the anti-reflective layer and the SiON layer. The SiON layer pattern is used as an etch mask to transfer the SiON layer pattern into the amorphous carbon layer. Thus, an amorphous carbon layer pattern, which can be used as an etch mask to pattern a material layer on a substrate, is formed. The amorphous carbon layer pattern is used to selectively etch the material layer therebelow. The ashing and stripping processes are performed to remove the residual amorphous carbon layer and impurities.

U.S. Pat. No. 6,573,030 discloses a method of patterning a material layer on a substrate using the amorphous carbon layer as an etch mask. In the U.S. Pat. No. 6,573,030, the amorphous carbon layer can be used as an anti-reflective layer. The amorphous carbon layer can also be used as an etch mask for fine patterning oxides or nitrides. However, in conventional method of forming patterns using an amorphous carbon layer, a SiON layer is used as the etch mask to etch an etch-resist amorphous carbon layer. The SiON layer is used to etch the etch-resist amorphous carbon layer because conventional photoresist layer having an acrylate structure cannot be used as an etch mask when etching the etch-resist amorphous carbon layer.

In a structure where the material layer, the amorphous layer, and the SION layer are deposited on the substrate, if the material layer is etched using the amorphous carbon layer as an etch mask, and the ashing and stripping processes are performed on the resulting structure, the SiON layer may be lifted in a bevel area of an edge of a wafer.

FIGS. 1 through 6C are cross-sectional views illustrating a pattern formation method using the conventional amorphous carbon layer/SiON layer/anti-reflective layer/photoresist layer deposition structure.

Referring to FIG.1, a material layer, e.g. a silicon nitride layer 5, is formed on a substrate 1. An amorphous carbon layer 6/SiON layer 7/anti-reflective layer 8/photoresist layer 9 deposition structure is formed on the silicon nitride layer 5 to pattern the silicon nitride layer 5. The photoresist layer 9 used to form a fine pattern is for ArF exposure. The photoresist layer 9 has an acrylate structure.

Referring to FIG. 2A, a photoresist layer pattern 9a is formed by exposure and development processes. FIG. 2B is a cross-sectional view illustrating a bevel area at an edge of a wafer where the photoresist pattern may not be formed. Referring to FIG. 2B, in the bevel area, the silicon nitride layer 5, the amorphous carbon layer 6, and the SiON layer 7 are formed on the substrate 1. The photoresist layer needs not to be formed in the bevel area because no pattern may be formed in the bevel area. Accordingly, the photoresist layer 9 formed in the bevel area needs to be removed not to act as a particle source during subsequent processes.

Referring to FIG.3, the anti-reflective layer 8 and the SiON layer 7 are selectively etched using the photoresist layer pattern 9a as an etch mask. The etch mask forms an anti-reflective layer pattern 8a and a SiON layer pattern 7a. As illustrated in FIG. 4, the SiON layer pattern 7a is used as an etch mask to selectively etch the amorphous carbon layer 6 to form an amorphous carbon layer pattern 6a. The amorphous carbon layer pattern 6a can be used as a hard mask, which can be used for fine patterning the underlying silicon nitride layer 5.

Referring to FIG. 5, the silicon nitride layer 5 is selectively etched using the amorphous carbon layer pattern 6a as an etch mask to form a silicon nitride layer pattern 5a. Referring to FIG. 6A, the residual amorphous carbon layer and impurities are removed using ashing and stripping treatments. An ashing treatment is performed using O₂ and N₂ plasma to remove, for example, residual impurities. The amorphous carbon layer can be removed using the ashing treatment.

However, during the ashing and stripping treatments, the SiON layer in the wafer bevel area may be lifted. FIG. 6B is a cross-sectional view of the wafer bevel area after the silicon nitride layer 5 is etched and ashing treatments are performed. Referring to FIG. 6B, a portion of the amorphous carbon layer 6 on a backside of the bevel area can be removed by the etching treatment. During the etching treatment, O₂ or N₂ plasma is injected into a region between the SiON layer 7 and the substrate 1, thereby etching the amorphous carbon layer 6. If a wet stripping treatment is performed thereafter, a lifting phenomenon can occur. That is, a portion 7′ of the SiON layer 7 on the backside of the bevel area may break off as shown in FIG. 6C. A portion of the SiON layer 7 on the backside of the bevel area, where the amorphous carbon layer 6 is removed, may be mechanically unstable.

Thus, the portion of the SiON layer 7 on the backside of the bevel area is likely to break off due to stress, which may be caused by the flow of a chemical during the stripping process. To prevent the lifting phenomenon on the SiON layer 7, a wafer edge treatment process can be performed after depositing the amorphous carbon layer 6 and before forming the SiON layer 7. During the wafer edge treatment process, the amorphous carbon layer 6 in the bevel area can be removed. However, the wafer edge treatment process may cause increased processing time and higher costs.

### SUMMARY OF THE INVENTION

In exemplary embodiments of the present invention, a silicon photoresist layer pattern is used to pattern an anti-reflective layer and an amorphous carbon layer. The patterned amorphous carbon layer can be an etch mask to form a pattern in an underlying material layer. Accordingly, an intermediate layer such as a SiON layer on the amorphous carbon layer may not be required. Furthermore, an additional wafer edge treatment process may not be required, thereby preventing a lifting phenomenon of a SiON layer in a bevel area.

In one exemplary embodiment of the present invention, a pattern formation method comprises forming a material layer on a substrate, forming an amorphous carbon layer on the material layer, forming an anti-reflective layer on the amorphous carbon layer, forming a silicon photoresist layer on the anti-reflective layer, forming a silicon photoresist layer pattern by patterning the silicon photoresist layer, etching the anti-reflective layer and the amorphous carbon layer using the silicon photoresist layer pattern as an etch mask to form an amorphous carbon layer pattern, and etching the material layer using the amorphous carbon layer pattern as an etch mask to form a pattern in the material layer.

According to another exemplary embodiment of the present invention, a pattern formation method comprises forming a barrier metal layer on a substrate, forming a line metal layer on the barrier metal layer, forming a silicon nitride layer on the line metal layer, forming an amorphous carbon layer on the silicon nitride layer, forming an anti-reflective layer on the amorphous carbon layer, forming a silicon photoresist layer on the anti-reflective layer, forming a silicon photoresist layer pattern by patterning the silicon photoresist layer, etching the anti-reflective layer and the amorphous carbon layer using the photoresist layer pattern as an etch mask to form an amorphous carbon layer pattern, etching the silicon nitride layer using the amorphous carbon layer pattern as an etch mask to form a silicon nitride layer pattern, performing ashing and stripping treatments, and etching the line metal layer and the barrier metal layer using the silicon nitride layer pattern as an etch mask to form a metal interconnection.

These and other exemplary embodiments, features and advantages of the present invention will become more apparent by describing in detail exemplary embodiments thereof with reference to the attached drawings.

### BRIEF DESCRIPTION OF THE DRAWINGS

FIGS. 1 through 6C are cross-sectional views illustrating a pattern formation method using a conventional amorphous carbon layer/SiON layer/anti-reflective layer/photoresist layer deposition structure.

FIGS. 7 through 12 are cross-sectional views illustrating a method of forming a silicon nitride layer pattern according to an exemplary embodiment of the present invention.

FIG. 13 is an SEM image of a cross section of an amorphous carbon layer pattern formed according to an exemplary embodiment of the present invention.

FIG.14 is an SEM image of a tungsten (W) interconnection pattern formed using the amorphous carbon layer pattern shown in FIG. 13.

FIGS. 15 through 18 are cross-sectional views illustrating a method of forming a via pattern according to another exemplary embodiment of the present invention.

FIGS. 19 through 24 are cross-sectional views illustrating a method of forming a trench pattern of a damascene process according to still another exemplary embodiment of the present invention.

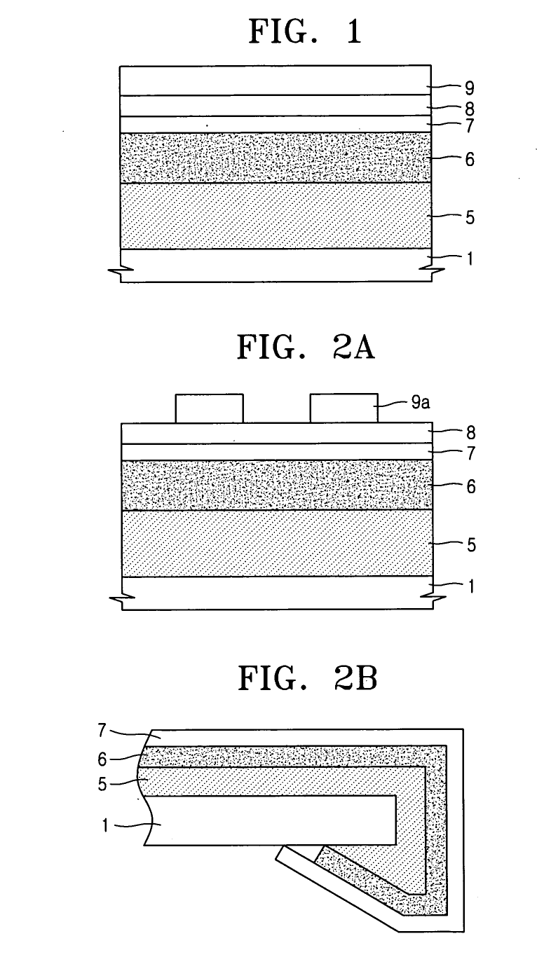

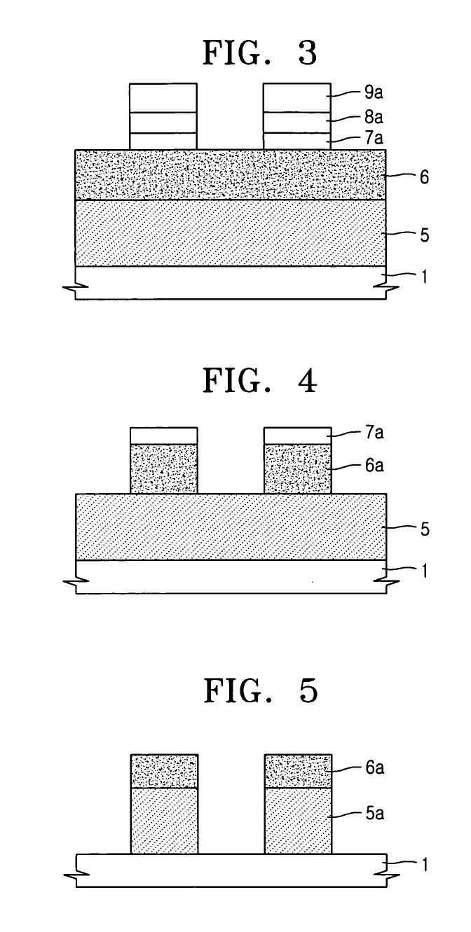

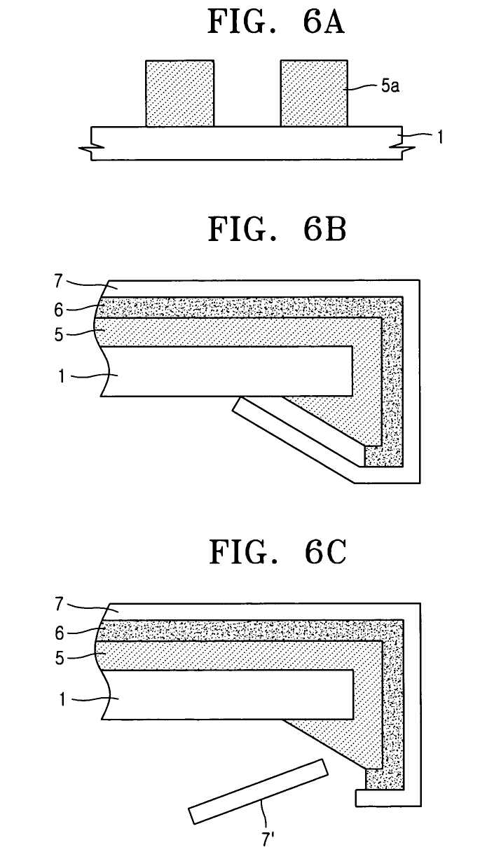

### DETAILED DESCRIPTION OF EXEMPLARY EMBODIMENTS

Exemplary embodiments of the present invention will now be described more fully with reference to the accompanying drawings. This invention may, however, be embodied in many different forms and should not be construed as being limited to the embodiments set forth herein. Rather, these embodiments are provided so that this disclosure will be through and complete, and will fully convey the concept of the invention to those skilled in the art. FIGS. 7 through 12 are cross-sectional views illustrating a method of forming a silicon nitride layer pattern according to an exemplary embodiment of the present invention. The silicon nitride layer pattern can be used to pattern an underlying metal layer such as a tungsten (W) layer for an interconnection pattern formation.

Referring to FIG.7, a barrier metal layer 102 including Ti/TiN, a line metal layer 103 including W, and a silicon nitride layer 105 are sequentially formed on an interlayer insulating layer 101 including SiO₂ on a semiconductor substrate. An amorphous carbon layer 106, an anti-reflective layer 108, and a silicon photoresist layer 109 are sequentially deposited thereon. The amorphous carbon layer 106 may have a thickness of, for example, about 1000 to about 5000 Å. The anti-reflective layer 108 may have a thickness of, for example, about 200 to about 600 Å. The silicon photoresist layer 109 may have a thickness of, for example, about 500 to about 2000 Å. The silicon photoresist layer 109 may be a photoresist layer for KrF or ArF exposure. In another exemplary embodiment of the present invention, F₂ can be used as a light source instead of ArF. Typically, the silicon photoresist pattern is used to pattern an underling organic layer such as novolak. The silicon photoresist layer may include Si, C, H, and O. The silicon photoresist has a ladder-like structure.

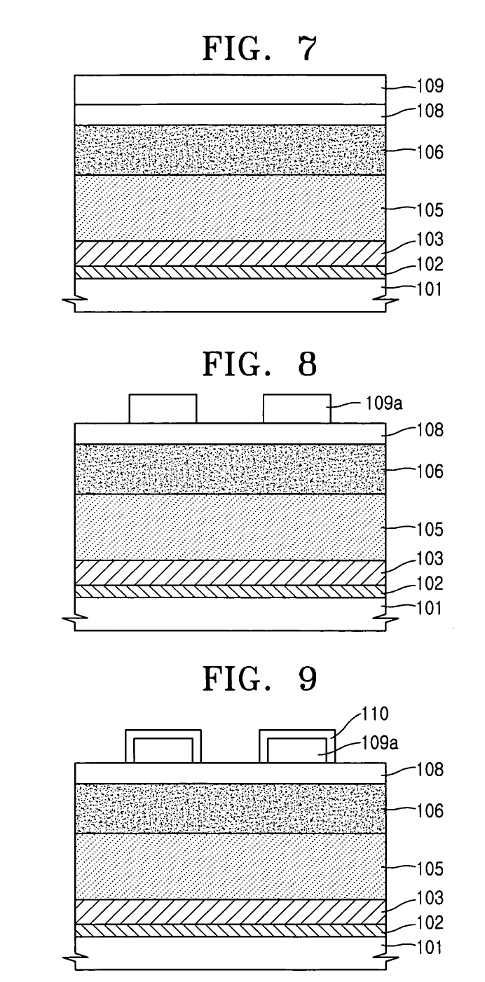

Referring to FIG. 8, the silicon photoresist layer 109 is patterned using exposure and development processes to form a silicon photoresist layer pattern 109a. Referring to FIG.9, a surface of the silicon photoresist layer pattern 109a is pre-oxidized under an O₂ plasma atmosphere to form an oxide layer 110 thereon. This pre-oxidation process may improve the etch selectivity for the amorphous carbon layer when etching the amorphous carbon layer 106.

Oxidizing gases used in this pre-oxidation process include O₂, HeO₂, or N₂O. N₂, He, Ar, or Ne can be added to the oxidizing gas. The pre-oxidation process may be performed using plasma equipments such as a dual frequency high density plasma (HDP) equipment capable of separating electric power. Alternatively, a dual frequency plasma source equipment can be used. During the pre-oxidation process, about 0 to about 50 W of electric power may be supplied to a chuck. A source and top portions of the pre-oxidation equipment can be supplied with about 300 to about 1500 W of electric power to increase the oxidation speed. The pre-oxidation process may be performed for about 5 to about 30 seconds. When the thickness of the silicon photoresist layer 109 is sufficient, the pre-oxidation process can be omitted.

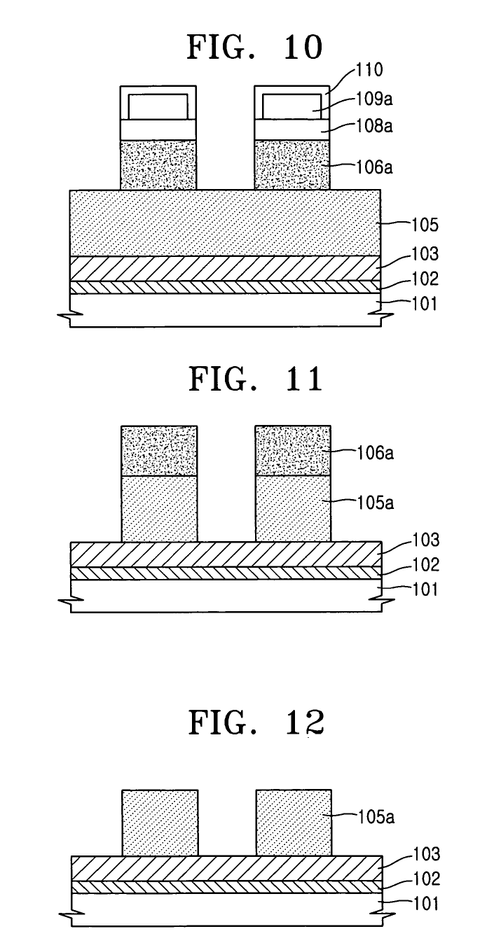

Referring to FIG. 10, the anti-reflective layer 108 and the amorphous carbon layer 106 are selectively etched using the silicon photoresist layer pattern 109a with the pre-oxidized layer 110 as an etch mask. Thus, an amorphous carbon layer pattern 106a can be obtained. The amorphous carbon layer pattern 106 is etched using an etch gas capable of producing oxygen radicals, such as O₂, HeO₂, or N₂O. An additive such as N₂, He, HBr, Ar, or Ne can be added to the etch gas. The pre-oxidation of the silicon photoresist layer pattern 109a and the etching of the amorphous carbon layer 106 can be performed in situ in a chamber.

Referring to FIG. 11, the silicon nitride layer 105 is selectively dry-etched using the amorphous carbon layer pattern 106a as an etch mask to form a silicon nitride layer pattern 105a. During the dry-etching, the anti-reflective layer pattern 108a and the silicon photoresist layer pattern 109a, which are formed on the amorphous carbon layer pattern 106a, can also be removed.

Referring to FIG. 12, the residual amorphous carbon layer pattern 106a and impurities may be removed by ashing and wet-stripping treatments. The silicon nitride layer pattern 105a is used to pattern the underlying line metal layer 103 and barrier metal layer 102 to form a metal interconnection pattern.

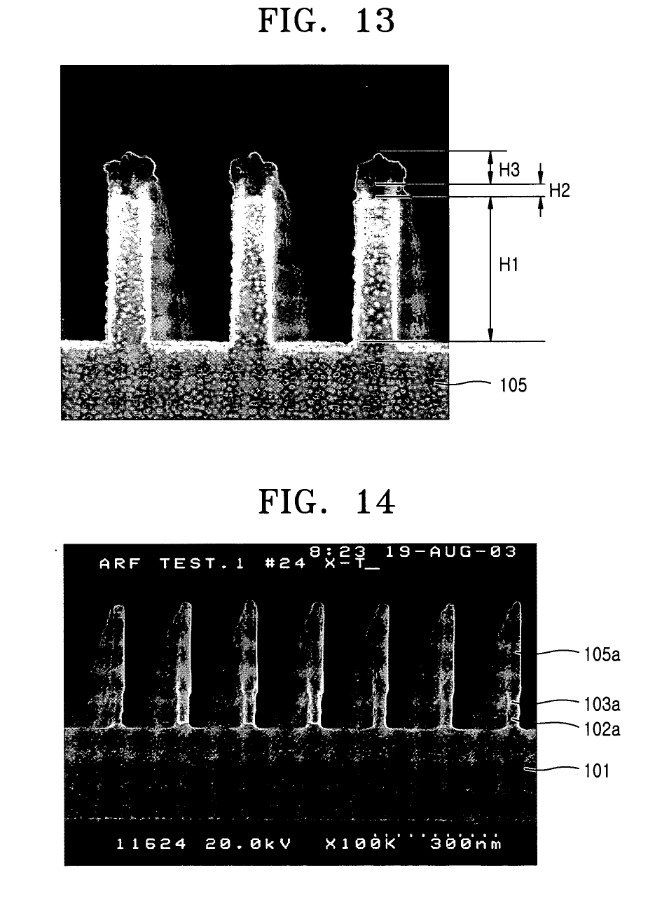

FIG. 13 is a Scanning Electron Microscopy (SEM) image illustrating a cross section of an amorphous carbon layer pattern formed according to an exemplary embodiment of the present invention. Referring to FIG. 13, an amorphous carbon layer pattern, an anti-reflective layer pattern, and a silicon photoresist layer pattern are formed on a silicon nitride layer 105. The amorphous carbon layer pattern can be formed with precision even though the amorphous carbon layer pattern has a large thickness (H1; for example about 2000 Å) compared to thicknesses of the silicon photoresist layer pattern (H3; for example about 600 Å) and the anti-reflective layer pattern (H2; for example about 300 Å).

FIG. 14 is an SEM image of a cross section of a tungsten (W) interconnection pattern formed using the amorphous carbon layer pattern shown in FIG. 13. Referring to FIG. 14, a barrier metal layer pattern 102a including Ti/TiN, an interconnection pattern 103a including W, and a silicon nitride layer pattern 105a are formed on an interlayer insulating layer 101 including SiO₂. The silicon nitride layer pattern 105a is formed by etching the silicon nitride layer 105 using the amorphous carbon layer pattern (referred to ‘H1’ shown in FIG. 13) as an etch mask. The barrier metal layer pattern 102a and the interconnection pattern 103a are patterned using the silicon nitride layer pattern 105a as an etch mask. The interconnection pattern 103a illustrated in the SEM image of FIG.14 is an ultra-fine tungsten interconnection pattern with a line width of about 30 nm. FIG. 14 shows that a fine interconnection pattern can be obtained using the pattern formation method according to an exemplary embodiment of the present invention.

The pattern formation method according to an exemplary embodiment of the present invention can be also applied to form contact and via patterns as well as interconnection patterns.

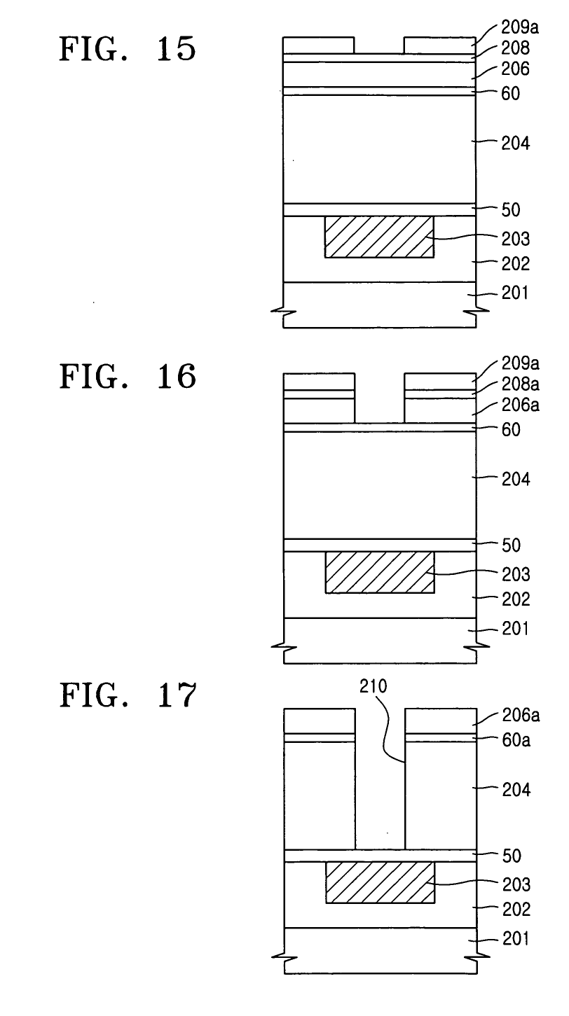

FIGS. 15 through 18 are cross-sectional views illustrating a method of forming a via pattern according to another exemplary embodiment of the present invention. The via pattern formation method may be applicable to a logic circuit unit.

Referring to FIG. 15, a first etch-resist layer 50, an inter-metal insulating layer 204, and a second etch-resist layer 60 are sequentially formed on a Cu interconnection 203 formed in a bottom insulating layer 202 on a substrate 201. To form a via pattern, an amorphous carbon layer 206, an anti-reflective layer 208, and a silicon photoresist layer are sequentially formed on the second etch-resist layer 60. Exposure and development processes are performed to form a silicon photoresist layer pattern 209a, which may be used to form a via hole. The silicon photoresist layer may be a silicon photoresist layer for KrF, ArF, or F2 exposure depending on a type of the light source.

Referring to FIG. 16, the anti-reflective layer 208 and the amorphous carbon layer 206 are selectively etched using the silicon photoresist layer pattern 209a as an etch mask to form an amorphous carbon layer pattern 206a. The amorphous carbon layer 206 is etched using an etch gas capable of producing oxygen radicals The etch gas includes O₂, HeO₂, or N₂O. The etch gas may further include an additive such as N₂, He, HBr, Ar, or Ne. As described above with reference to FIG. 9, the exemplary embodiment may also include a pre-oxidation process. The pre-oxidation process can be performed on a surface of the silicon photoresist layer pattern before etching the anti-reflective layer 208 and the amorphous carbon layer 206. The pre-oxidation of the silicon photoresist layer and the etching of the amorphous carbon layer 206 can be performed in situ in a chamber.

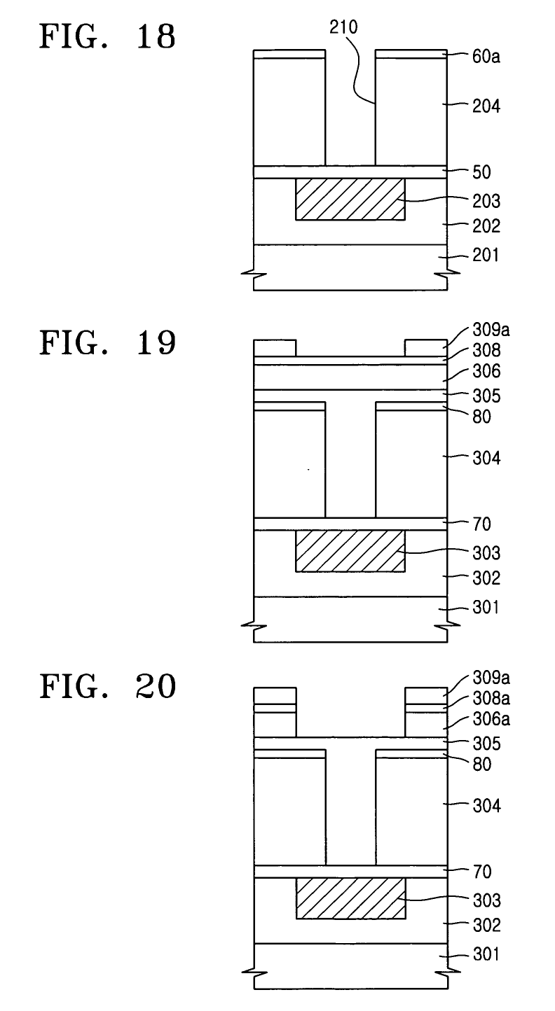

Referring to FIG. 17, the second etch-resist layer 60 and the interlayer insulating layer 204 are anisotropically dry-etched using the amorphous carbon layer pattern 206a as an etch mask to form a via hole 210 in the inter-metal insulating layer 204. Referring to FIG. 18, the residual amorphous carbon layer pattern 206a and impurities can be removed by ashing and wet stripping treatments. An exposed portion of the first etch-resist layer 50 is etched. Cu is deposited to fill the via hole 210. The deposited Cu is planarized, for example, using CMP process. A via pattern contacting a Cu interconnection 203 is formed.

The pattern formation method according to an exemplary embodiment of the present invention can be applied to trench pattern formation of a damascene process. FIGS. 19 through 24 are cross-sectional views illustrating a trench pattern formation method of a damascene process according to another exemplary embodiment of the present invention.

Referring to FIG. 19, a etch-resist layer 70, an inter-metal insulating layer 304, and a capping layer 80 are sequentially formed on a Cu interconnection 303 formed in a bottom insulating layer 302 on a substrate 301. A via hole, which is formed in the inter-metal insulating layer 304, is filled and the capping layer 80 is covered with a fluid oxide layer 305 such as spin-on glass (SOG). An amorphous carbon layer 306, an anti-reflective layer 308, and a silicon photoresist layer are formed on the fluid oxide layer 305. Exposure and development processes are performed to form a silicon photoresist layer pattern 309a. Referring to FIG. 20, the anti-reflective layer 308 and the amorphous carbon layer 306 are selectively etched using the silicon photoresist layer pattern 309a as an etch mask to form an amorphous carbon layer pattern 306a. As described above with reference to FIG. 9, a pre-oxidation process can also be performed on a surface of the silicon photoresist layer pattern 309a before etching the anti-reflective layer 308 and the amorphous carbon layer 306.

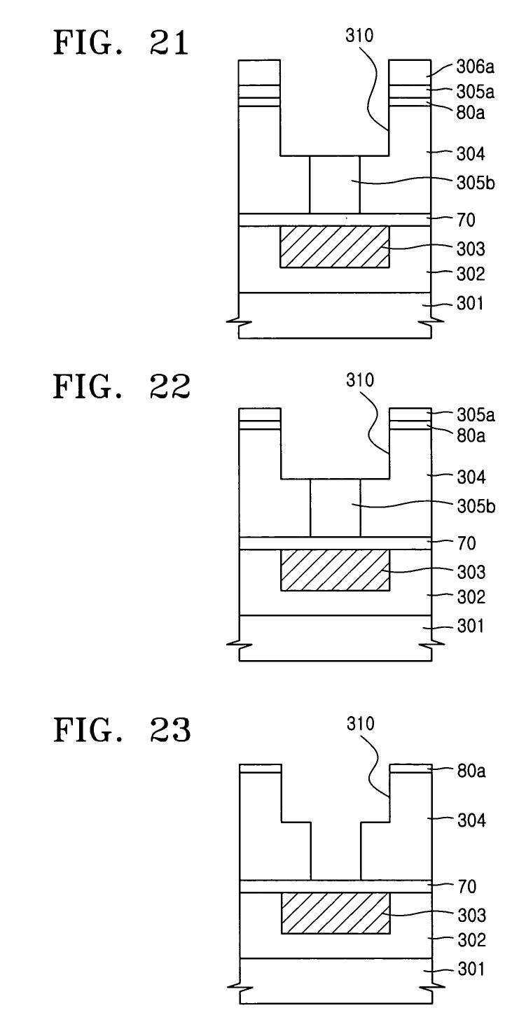

Referring to FIG. 21, the fluid oxide layer 305 and the capping layer 80 are anisotropically dry etched to form a trench 310 using the amorphous carbon layer pattern 306a as an etch mask. As illustrated in FIG. 22, etching and wet stripping treatments may be performed to remove the residual amorphous carbon layer pattern 306a and impurities.

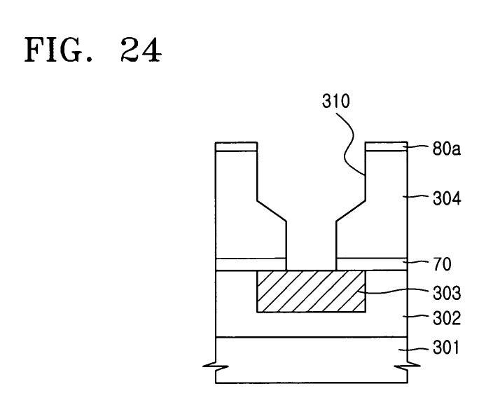

Referring to FIG. 23, a residual fluid oxide layer 305a on a capping layer 80a, and a residual fluid oxide layer 305b below the trench 310 can be removed by wet etching to form a via hole that contacts the trench 310. Referring to FIG. 24, a portion of the etch-resist layer 70 on the Cu interconnection 303 is selectively wet-etched using the capping layer pattern 80a as an etch mask. A via hole, and a trench pattern are formed. Through the via hole, the Cu interconnection 303 can be exposed. A Cu layer may fill the via hole and the trench 310. The Cu layer may be planarized, thereby completing a Cu interconnection structure.

Although exemplary embodiments have been described herein with reference to the accompanying drawings, it is to be understood that he present invention is not limited to those precise embodiments, and that various other changes and modifications may be affected therein by one ordinary skill in the related art without departing from the scope of spirit of the invention. For example, a material layer patterned according to exemplary embodiments of the present invention on a substrate may be a polysilicon layer instead of the above-mentioned silicon nitride layer or silicon oxide layer.

1. A pattern formation method comprising:
forming a material layer on a substrate;
forming an amorphous carbon layer on the material layer;
forming an anti-reflective layer on the amorphous carbon layer;
forming a silicon photoresist layer on the anti-reflective layer;
forming a silicon photoresist layer pattern by patterning the silicon photoresist layer;
etching the anti-reflective layer and the amorphous carbon layer using the silicon photoresist layer pattern as an etch mask to form an amorphous carbon layer pattern; and
etching the material layer using the amorphous carbon layer pattern as an etch mask to form a pattern in the material layer.

2. The pattern formation method of claim 1, further comprising pre-oxidizing a surface of the silicon photoresist layer pattern after forming the silicon photoresist layer pattern.

3. The pattern formation method of claim 1, further comprising performing ashing and stripping treatments after etching selectively the material layer.

4. The pattern formation method of claim 1, wherein the material layer includes silicon oxide, silicon nitride, or polysilicon.

5. The pattern formation method of claim 1, wherein the silicon photoresist layer includes C, H, O, and Si, and has a ladder-like network structure.

6. The pattern formation method of claim 1, wherein the silicon photoresist layer pattern is formed for forming an interconnection line.

7. The pattern formation method of claim 1, wherein the silicon photoresist layer pattern is formed for forming a contact.

8. The pattern formation method of claim 1, wherein the silicon photoresist layer pattern is formed for forming a trench.

9. The pattern formation method of claim 1, wherein the silicon photoresist layer pattern is formed for forming a via hole.

10. The pattern formation method of claim 1, wherein the silicon photoresist layer includes a photoresist layer for KrF exposure, a photoresist layer for ArF exposure, and a photoresist layer for F₂ exposure.

11. The pattern formation method of claim 1, wherein the thickness of the amorphous carbon layer is about 1000 to about 5000 Å

12. The pattern formation method of claim 1, wherein the thickness of the silicon photoresist layer is about 500 to about 2000 Å.

13. The pattern formation method of claim 1, wherein the amorphous carbon layer is etched using an etch gas including O₂, HeO₂, or N₂O.

14. The pattern formation method of claim 1, wherein the amorphous carbon layer is etched using an additive including N2, He, HBr, Ar, or Ne.

15. The pattern formation method of claim 2, wherein the surface of the silicon photoresist layer pattern is pre-oxidized using an oxidizing gas including O₂, HeO₂, or N₂O.

16. The pattern formation method of claim 2, wherein the surface of the silicon photoresist layer pattern is pre-oxidized using an additive including N₂, He, Ar, or Ne.

17. The pattern formation method of claim 2, wherein the pre-oxidizing of the surface of the silicon photoresist layer, and the etching of the anti-reflective and the amorphous carbon layer are performed in situ in a chamber.

18. The pattern formation method of claim 2, wherein the pre-oxidizing is performed using one of a dual frequency high density plasma (HDP) source capable of separating electric power or a dual frequency plasma source.

19. The pattern formation method of claim 2, wherein the pre-oxidizing supplies about 0 to about 50 W of electric power to a chuck inside of a pre-oxidation equipment and about 300 to about 1500 W of electric power to source and upper portions of the pre-oxidation equipment.

20. The pattern formation method of claim 2, wherein the pre-oxidizing is performed for about 5 to about 30 seconds.

21. A pattern formation method comprising:
forming a barrier metal layer on a substrate;
forming a line metal layer on the barrier metal layer;
forming a silicon nitride layer on the line metal layer;
forming an amorphous carbon layer on the silicon nitride layer;
forming an anti-reflective layer on the amorphous carbon layer;
forming a silicon photoresist layer on the anti-reflective layer;
forming a silicon photoresist layer pattern by patterning the silicon photoresist layer;
etching the anti-reflective layer and the amorphous carbon layer using the photoresist layer pattern as an etch mask to form an amorphous carbon layer pattern;
etching the silicon nitride layer using the amorphous carbon layer pattern as an etch mask to form a silicon nitride layer pattern;
performing ashing and stripping treatments; and
etching the line metal layer and the barrier metal layer using the silicon nitride layer pattern as an etch mask to form a metal interconnection.

22. The pattern formation method of claim 21, further comprising pre-oxidizing a surface of the photoresist layer pattern after forming the silicon photoresist layer pattern.

23. The pattern formation method of claim 21, wherein the anti-reflective layer and the amorphous carbon layer are etched anisotropically.
